(19) United States
(12) Patent Application Publication
(10) Pub. No.: US 2007/0109881 A1
(43) Pub. Date: May 17, 2007

(54) Management of defective blocks in flash memories

(75) Inventor: Reinhard Kuhne, Reichenau (DE)

Correspondence Address: BROWDY AND NEIMARK, P.L.L.C.;624 NINTH STREET, NW, SUITE 300, WASHINGTON, DC, 20001-5303, US

(73) Assignee: HYPERSTONE AG, KONSTANZ (DE)

(21) Appl. No.: 10/571,589

(22) PCT Filed: Aug. 12, 2004
(86) PCT No.: PCT/EP04/51785

§ 371 Date: Dec. 18, 2006

(30) Foreign Application Priority Data
Sep. 10, 2003 (DE) 10341616.1

(51) Int. Cl. G11C 29/00

(52) U.S. Cl. 365/200

(57) ABSTRACT

The invention relates to a method for the management of defective memory blocks in a non-volatile memory system comprising individually erasable memory blocks (SB) that can be addressed with the aid of real memory block addresses (SBA). Said memory blocks can be addressed by means of an address conversion that uses an allocator table (ZT) to convert logical block addresses (LBA) into one of the respective memory block addresses (SBA). According to the invention, the allocator table (ZT) is sub-divided into at least one useful data area (NB), a buffer block area (BB), a defect area (DB) and a reserve area (RB). If an error occurs during the erasure process, the relevant block is replaced by a reserve block and its memory block address is written to the defect area (DB).

The invention is related to a method to manage defective memory blocks in a non-volatile memory system comprising individually erasable memory blocks, that can be addresses with the aid of real memory block addresses Said memory block addresses can be addressed by means of an address conversion that uses an allocator table to convert logical block addresses into one of the respective memory block addresses. The allocator table is sub-divided into at least one useful data area, a buffer block area, a defect area and a reserve area.

Flash memories are used in many computer systems, in particular in changeable memory cards for digital cameras and portable computers. Flash memories are organised in memory blocks, each with a lot of sectors. The limited number of write and erase operations and the erasure of only large memory blocks are essential features of these memories. Thereby the write and erase operations need much more time (up to a factor of 50) as the read operation. The memory blocks are weared out through many write and erase operations and then they are no longer reliable at writing and erasure.

Through wear levelling, as described in i.e. in the patent application DE 198 40 389, an approximately equal number of erase operations is achieved. As through modern production technology the quality and with it the frequency of erase operations are similar for all memory cells, management methods can be used, which are equal for all memory blocks.

With known methods, i.e. with the patent application EP 0,617,363, by recognition of a defect block this will be substituted by a reserve block und these two are chained in a table. Furthermore, a table on defect memory cells is maintained. Such methods tend to a longer seek in tables to find the valid memory block to a memory operation.

It is the task of the invention to manage defective memory blocks in such a way, that they are no longer included in memory operations.

This task is solved in that if an error occurs during an erase process the relevant block is replaced by a reserve block and its memory block address is written into the defect area. Favourable embodiments of the invention are specified in the dependent claims.

The considered memory system with non-volatile memory cells is organised in memory blocks, which are individually erasable with an erasure operation.

Die memory blocks are addressed by their memory block address. The logical block addresses, given by a host system, are converted into memory block addresses by means of an allocator table. Thereby the logical block addresses are allocated in continuous order. The logical block address serves as index into the allocator table, in which to each logical address a memory block address is registered, which in use can be exchanged with other memory block addresses. In addition for each memory block flags are maintained in the table. The allocator table is divided into at least four areas: a useful data area, a buffer block area, a reserve area and a defect area, which attach directly together. The useful data area is the by far largest area. For a memory system with 1000 memory blocks division could be for example arranged as follows: 944 useful data blocks, 4 buffer blocks, first 52 reserve blocks and 2 defect blocks. On occurrence of an error at an erasure operation, the entry of the memory block in the allocator table is exchanged with a reserve block and its address is registered into the defect area.

Favourable the defect area is in each case only so large, as defective blocks have been registered. If a new defective block is recognized, the defect area is increased by an entry and the reserve area is reduced by an entry. The total volume of the reserve area plus the defect area does remain constant and there are no further table changes necessary.

Since all memory cells have about the same probability of defect, and favourable the erase frequency is adapted through “wear levelling” of all memory blocks, the relationship between defective and reserve blocks indicates the quality and the total wear of the memory system, which can be simply evaluated.

If an error is recognized during the writing into a memory block, it is marked by the flag “defect”. Since only few bits are wrong with such an error, the bit errors are corrected by means of the check bytes during the reading of this block and the correct contents is reproduced. Only before the next writing to the as “defect” characterized memory block this is exchanged with another memory block from the buffer area.

The erasure of used and no longer valid memory blocks is favourable done by a background program, which evaluates appropriate flags to the memory blocks. If this program detects a memory block characterized with the flag “is defect”, this is not erased, but is directly exchanged with a reserve block. In the future the defective block is not any longer used.

A favourable embodiment of the invention is described exemplarily in the figures.

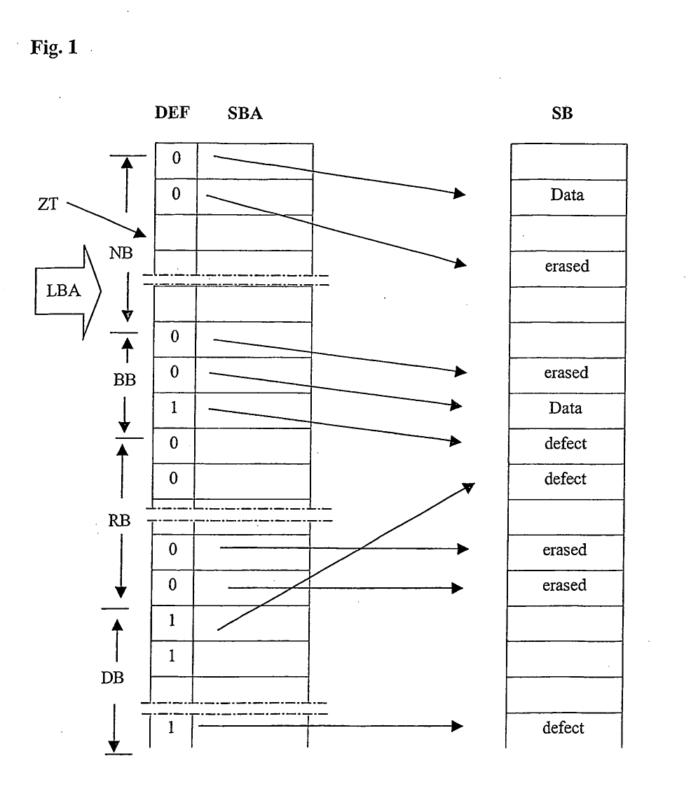

FIG. 1 shows the structure of the allocator table to the memory blocks at the occurrence of a defect.

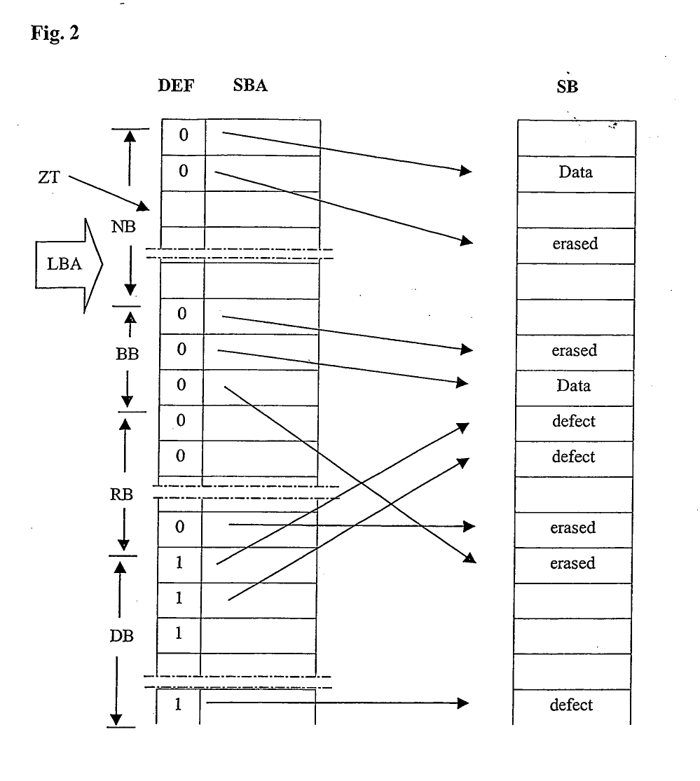

FIG. 2 shows the allocator table after clearing due to a write error

In FIG. 1 the allocator table time is represented, which is divided into four areas. The first area is the useful data area NB, which takes the by far largest part of the table. Then the buffer block area BB with some pointers to buffer blocks. The reserve area contains pointers to erase blocks, which stand ready as spare. The defect area points only to defective blocks. The allocator table is accessed with a logical block address LBA and then the there registered memory block address SBA is used for the memory operation. The memory blocks SB can contain data, can be erased (“erased”) or defective(“defect”). Write operations to a memory block SB use normally a buffer block. If during the write operation it is recognized that the memory block is defective, the flag DEF is set and a new buffer block from the reserve area is used.

In FIG. 2 the situation of the allocator table time is shown after clearing of the write error. The buffer block pointer, which pointed first to a defective memory block SB, points now to an erased memory block, which was assigned so far to the reserve area RB. The reserve area RB is reduced by one entry and the defect area DB is enlarged by one entry. The border between both areas is shifted by one entry. The total sum of the assigned blocks to the two areas remained constant.

1. Method for the management of defective memory blocks in a non-volatile memory system with individually erasable memory blocks (SB), addressable with real memory block addresses (SBA), and which are addressable with an address conversion by means of an allocator table (ZT) of logical block addresses (LBA) into one of the real memory block addresses (SBA) in each case, wherein the allocator table (ZT) is divided at least into one useful data area (NB), a buffer block area (BB), a defect area (DB) and a reserve area (RB), characterized in that after an error with the erasure, the corresponding block is exchanged against a reserve block and its memory block address is registered into the defect area (DB).

2. Method according to claim 1, characterized in that the defect area (DB) is as large as defective blocks are present in each case.

3. Method according to claim 2, characterized in that the defect area (DB) is increased by one on registering a defective block and the reserve area (RB) is reduced by one.

4. Method according to claim 3, characterized in that the quality of the memory is determined by the relationship of the reserve area (RB) to the defect area (DB).

5. Method according to claim 1, characterized in that after errors during the write operation into a memory block (SB) the corresponding block is marked by the flag “defect” (DEF).

6. Method according to claim 5, characterized in that a background program scans the allocator table (ZT) for memory blocks (SB), which can be erased and does erase these, but if such a memory block is marked with the flag “defect”, does not erase this, but registers it into the defect area (DB).
